(19) United States
(12) Patent Application Publication
(10) Pub. No.: US 2026/0068172 A1
(43) Pub. Date: Mar. 5, 2026

(54) SELECTION ELEMENT USING FERROELECTRIC AND X-POINT MEMORY DEVICE INCLUDING THE SAME

(71) Applicant: POSTECH RESEARCH AND BUSINESS DEVELOPMENT FOUNDATION, Pohang-si (KR)

(72) Inventors: Hyunsang HWANG, Pohang-si (KR); Lae Yong JUNG, Pohang-si (KR)

(21) Appl. No.: 19/311,697

(22) Filed: Aug. 27, 2025

(30) Foreign Application Priority Data
Sep. 2, 2024 (KR) 10-2024-0118871

(51) Int. Cl. H10B 63/00; H10N 70/00

(52) U.S. Cl. CPC H10B 63/24; H10B 63/84; H10N 70/8822; H10N 70/8828

(57) ABSTRACT

Disclosed are a selection element using a ferroelectric and an x-point memory device including the same. The selection element according to the present disclosure includes a first electrode; an ovonic threshold switch layer disposed on the first electrode; and a second electrode disposed on the ovonic threshold switch layer, wherein a ferroelectric layer is disposed between the first electrode and the ovonic threshold switch layer, and the ferroelectric layer and the ovonic threshold switch layer have a thickness ratio of 1:4 to 1:8.

### CROSS-REFERENCE TO RELATED APPLICATION

This application claims priority under 35 U.S.C § 119 to Korean Patent Application No. 10-2024-0118871 filed on Sep. 2, 2024, in the Korean Intellectual Property Office, the entire contents of which are hereby incorporated by reference.

### TECHNICAL FIELD

The present disclosure relates to a selection element for a memory device, and more particularly, to a selection element using a ferroelectric material in combination with an ovonic threshold switch.

Additionally, the present disclosure relates to an x-point memory device including the selection element.

Additionally, the present disclosure relates to a method for manufacturing a selection element for a memory device, which provides an excellent memory window expansion effect.

### BACKGROUND

Recently, developments have been made in variable resistance memory devices such as resistive random access memory (RRAM) and phase-change random access memory (PRAM). Such resistance-change memory devices are characterized in that a resistance change layer between a second electrode and a first electrode switches to a low resistance state (LRS) or a high resistance state (HRS) through the application of a voltage.

Resistance-change memory basically has a simple two-terminal structure of metal/insulator (oxide thin film)/metal, and implements a low resistance state (LRS) and a high resistance state (HRS) by utilizing the formation or rupture of a conductive filament through the movement of oxygen vacancies inside the element induced by an external voltage.

In order to integrate a resistance-change memory element into an x-point memory device, a selection element that functions as a switch to suppress leakage current is required.

FIG. 1 schematically illustrates a selection element for a memory device according to the related art.

Referring to FIG. 1, a conventional selection element for a memory device includes an ovonic threshold switch (OTS) layer 120 disposed on a first electrode 110, and a second electrode 130 disposed on the ovonic threshold switch layer 120. That is, in the conventional selection element for a memory device, an ovonic threshold switch layer 120 is disposed between the first electrode 110 and the second electrode 130.

The conventional selection element based on an ovonic threshold switch has a narrow memory window and also has the disadvantage that expanding the memory window is difficult.

### SUMMARY

It is an object of the present disclosure to provide a selection element for a memory device that exhibits excellent memory window expansion effect.

It is also an object of the present disclosure to provide an x-point memory device that exhibits excellent memory window expansion effect.

It is also an object of the present disclosure to provide a method for manufacturing a selection element for a memory device that exhibits excellent memory window expansion effect.

According to some aspects, a selection element may include a first electrode, an ovonic threshold switch layer disposed on the first electrode, and a second electrode disposed on the ovonic threshold switch layer, wherein a ferroelectric layer may be disposed between the first electrode and the ovonic threshold switch layer, and the ferroelectric layer and the ovonic threshold switch layer may have a thickness ratio of 1:4 to 1:8.

Here, the ovonic threshold switch layer and the ferroelectric layer may be in direct contact with each other.

Here, the ferroelectric layer may include zirconium-doped hafnium oxide.

Here, the atomic ratio of zirconium to hafnium may be from 1:3 to 3:1.

Here, the ferroelectric layer 240 may have a thickness of 10 nm or less.

Here, the ovonic threshold switch layer may include a chalcogenide compound. Here, the ovonic threshold switch layer may preferably include a chalcogenide compound containing at least one of Te and Se. More preferably, the ovonic threshold switch layer may include SiTeAsGe or SiTeSeAsGe.

Here, a carbon layer may be further disposed between the ovonic threshold switch layer and the second electrode.

According to some aspects, an x-point memory device may include m bit lines arranged in a first direction, where m is a natural number of 1 or more, n word lines arranged in a second direction intersecting the first direction and disposed apart from the m bit lines, where n is a natural number of 1 or more, and m×n selection elements disposed between the m bit lines and the n word lines, wherein each of the selection elements may be formed in a stacked structure of an ovonic threshold switch layer and a ferroelectric layer, and the ferroelectric layer and the ovonic threshold switch layer may have a thickness ratio of 1:4 to 1:8.

Here, the ovonic threshold switch layer and the ferroelectric layer may be in direct contact with each other.

The ferroelectric layer may be disposed between the ovonic threshold switch layer and the bit line.

Here, the ferroelectric layer may include zirconium-doped hafnium oxide.

Here, an atomic ratio of zirconium to hafnium may be in the range of 1:3 to 3:1.

Here, the ferroelectric layer 240 may have a thickness of 10 nm or less.

Here, the ovonic threshold switch layer may include a chalcogenide compound.

Here, a carbon layer may be additionally included between the selection element and the word line.

According to some aspects, a method of manufacturing a selection element may include forming a first electrode on a substrate, forming a ferroelectric layer on the first electrode, forming an ovonic threshold switch layer on the ferroelectric layer, and forming a second electrode on the ovonic threshold switch layer.

In the ovonic threshold switch layer formation step, the ovonic threshold switch layer may be formed such that the ovonic threshold switch layer is in direct contact with the ferroelectric layer.

Here, the ferroelectric layer may include zirconium-doped hafnium oxide.

Here, the atomic ratio of zirconium to hafnium may be from 1:3 to 3:1.

The ferroelectric layer may be formed by an atomic layer deposition method.

Here, the ferroelectric layer 240 may have a thickness of 10 nm or less.

The ferroelectric layer formation step and the ovonic threshold switch layer formation step may be performed such that the resistance ratio between the ferroelectric layer and the ovonic threshold switch layer is in a range of 1:3 to 3:1.

Here, the ovonic threshold switch layer may include a chalcogenide compound. Here, the ovonic threshold switch layer may preferably include a chalcogenide compound containing at least one of Te and Se. More preferably, the ovonic threshold switch layer may include SiTeAsGe or SiTeSeAsGe.

The ovonic threshold switch layer may be formed by a sputtering method.

After the step of forming the ovonic threshold switch layer, the method may additionally include a step of forming a carbon layer on the ovonic threshold switch layer.

Here, the first electrode and/or the second electrode may be formed by a sputtering method.

The selection element according to the present disclosure includes a ferroelectric layer together with an ovonic switch layer. As a result, an additional memory window effect may be obtained through the current polarization of the ferroelectric layer, allowing a larger memory window to be secured compared to the conventional technology.

Additionally, the selection element according to the present disclosure does not include any other material layer between the ovonic threshold switch layer and the ferroelectric layer, so the polarization phenomenon of the ferroelectric layer may affect the ovonic threshold switch layer.

In particular, in the case of the present disclosure, by using a ferroelectric material such as zirconium-doped hafnium oxide, which exhibits ferroelectric properties even at very thin thicknesses, the additional memory window effect remains excellent even when the thickness of the ferroelectric layer is 10 nm or less.

Additionally, the present disclosure has potential applicability not only in the field of general non-volatile memory, but also in areas such as computing express link (CXL), due to its cost advantage resulting from high speed and a simplified process.

In addition to the aforementioned effects, the specific effects of the present disclosure will be described in detail below along with specific embodiments for carrying out the disclosure.

### BRIEF DESCRIPTION OF THE DRAWINGS

Referring to the drawings, various embodiments of the present disclosure are illustrated in detail by way of example rather than limitation.

FIG. 1 schematically illustrates a selection element for a memory device according to the related art.

FIG. 2 schematically illustrates a selection element for a memory device according to an embodiment of the present disclosure.

FIG. 3 schematically illustrates a x-point memory device including the selection element structure of FIG. 2.

FIG. 4 schematically illustrates a selection element for a memory device according to another embodiment of the present disclosure.

FIG. 5 illustrates the direction of remanent polarization of a ferroelectric layer according to the pulse direction during a write operation.

FIG. 6 illustrates write pulses for creating a low threshold voltage state and a high threshold voltage state.

FIG. 7 illustrates the difference in the degree of threshold voltage variation between a single structure and an integrated structure, showing the additional effect achieved in the integrated structure.

FIG. 8A illustrates the change in current value according to voltage for a ferroelectric material alone that forms the ferroelectric layer in a ferroelectric tunnel junction memory (FTJ memory).

FIG. 8B illustrates the current value according to voltage for a chalcogenide compound alone that forms the ovonic threshold switch layer.

FIG. 9 is a graph showing that the off current density of the ferroelectric layer is maintained as the area of the ferroelectric material is reduced.

FIGS. 10A and 10B are current-voltage graphs illustrating the operation of the element when integrated under a condition where there is a large resistance difference between the ferroelectric layer and the ovonic threshold switch layer.

FIG. 11A illustrates a current-voltage curve indicating the expected magnitude of threshold voltage variation, considering the resistance of the ferroelectric layer and the ovonic switching layer, and FIG. 11B illustrates a current-voltage curve obtained through actual measurement.

FIG. 12 illustrates a current-voltage curve showing the threshold voltage according to pulse direction in a single memory with an ovonic switching-based selection element using a Te-based material.

FIG. 13 illustrates the additional threshold voltage variation obtained purely by the ferroelectric layer.

FIG. 14 illustrates a current-voltage curve showing the threshold voltage according to pulse direction in a single memory with an ovonic switching-based selection element using a Se-based material.

FIG. 15 illustrates a current-voltage curve showing the threshold voltage according to pulse direction in a mixed structure with a ferroelectric layer.

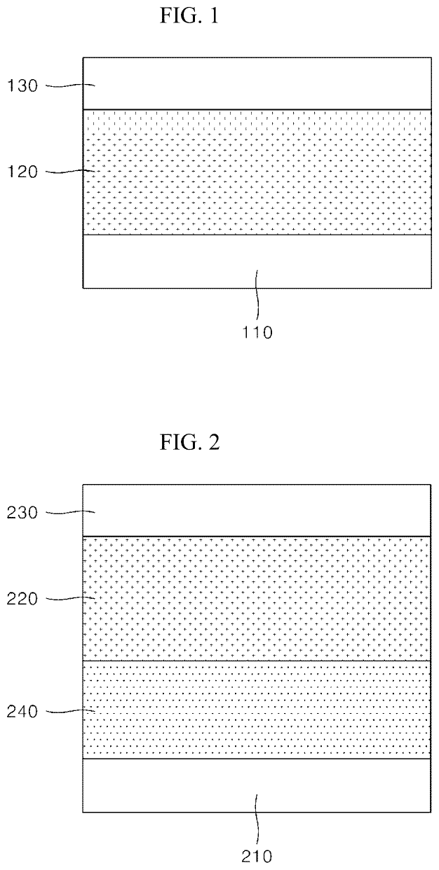

### DETAILED DESCRIPTION OF THE PREFERRED EMBODIMENTS

Advantages and features of the present disclosure, and methods for achieving them, will be clearly understood from the following detailed description of exemplary embodiments with reference to the accompanying drawings. However, the present disclosure is not limited to the embodiments disclosed below, but may be implemented in various different forms by those of ordinary skill in the art to which the present disclosure pertains.

Throughout the specification, like reference numerals refer to the same or similar components. The drawings are not necessarily to scale, and the sizes and relative proportions of layers and regions in the drawings may be exaggerated to more clearly illustrate specific features.

The expression that one component is “on” or “above” another component includes not only the case where it is directly on the other component, but also the case where another component is interposed in between. In contrast, the expression that one component is “directly on” or “immediately above” another component indicates that no other component is interposed therebetween. Also, when a component is described as being “connected,” “coupled,” or “joined” to another component, it is to be understood that the components may be directly connected or joined, but may also be connected, coupled, or joined through one or more other components interposed therebetween.

Spatially relative terms such as “below,” “lower,” “above,” and “upper” are used to describe the relationship between components as illustrated in the drawings, and should be understood as being provided to facilitate the description of such relationships. Spatially relative terms are to be understood as including orientations in addition to those illustrated in the drawings, for example, different orientations of the device during use or operation. For example, if the device illustrated in the drawings is turned over, a component described as being “below” another component may be positioned “above” the other component. Accordingly, exemplary terms such as “below” may include both downward and upward directions.

The terms used in the present specification are intended for the purpose of describing exemplary embodiments, and thus are not intended to limit the present disclosure. In the present specification, the singular forms include the plural forms unless otherwise specifically stated. The terms “include” and/or “including” as used in the specification do not exclude the presence or addition of one or more other components, steps, actions, and/or elements apart from the ones mentioned.

Hereinafter, preferred embodiments of a selection element using a ferroelectric according to the present specification, and a x-point memory device including the same, will be described in detail with reference to the accompanying drawings.

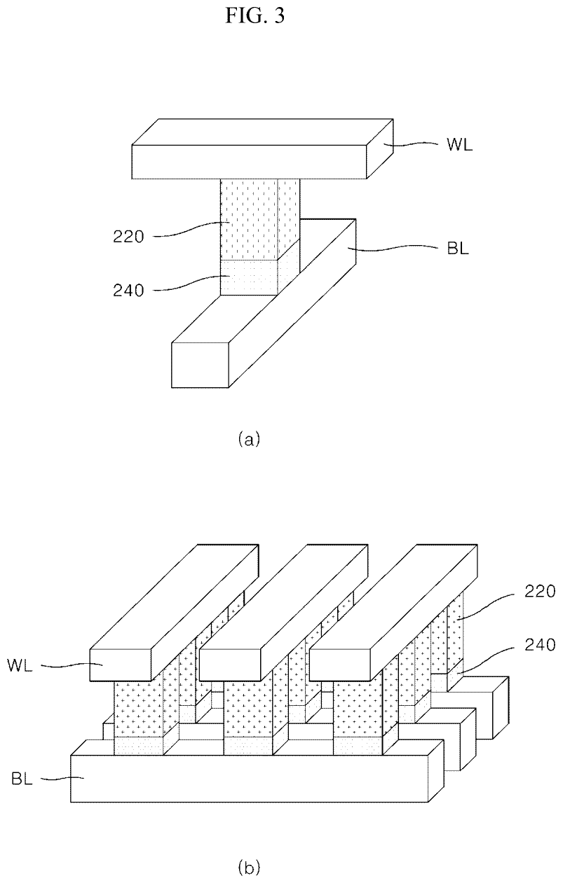

FIG. 2 schematically illustrates a selection element for a memory device according to an embodiment of the present disclosure.

Referring to FIG. 2, the illustrated selection element includes a first electrode 210, an ovonic threshold switch (OTS) layer 220, and a second electrode 230. In particular, the selection element illustrated in FIG. 2 includes a ferroelectric layer 240 disposed between the first electrode 210 and the ovonic threshold switch (OTS) layer 220. That is, in the selection element according to the present disclosure, the ovonic threshold switch (OTS) layer 220 and the ferroelectric layer 240 are disposed between the first electrode 210 and the second electrode 230.

The first electrode 210 and the second electrode 230 may be formed of a material having low reactivity, excellent corrosion resistance, and high electrical conductivity. For example, the first electrode 210 and the second electrode 230 may include one or more of gold (Au), platinum (Pt), tungsten (W), or titanium nitride (TiN).

The ovonic threshold switch layer 220 may be formed of various known materials, but preferably may include a chalcogenide compound. A chalcogenide compound is a compound including one or more of sulfur(S), selenium (Se), and tellurium (Te), and it exhibits excellent switching characteristics. The ovonic threshold switch layer 220 may, for example, be formed of a chalcogenide compound such as GeSbTe, SiTeAsGe, SiTeSeAsGe, AlAsTe, AlGeAsTe, or SiSbTe. More preferably, the ovonic threshold switch layer may include a chalcogenide compound containing at least one of Te and Se. Most preferably, the ovonic threshold switch layer may include SiTeAsGe or SiTeSeAsGe.

The ovonic threshold switch layer 220 may be formed as a thin film, for example, by vacuum thermal evaporation. The ovonic threshold switch layer 220 may be formed to have a thickness of approximately 20 nm to approximately 50 nm, and preferably, from the perspective of resistance ratio adjustment with the ferroelectric layer 240, may be formed to have a thickness of approximately 20 nm to approximately 30 nm. However, as will be described later, in order to reduce the difference in resistance levels between the ferroelectric layer 240 and the ovonic threshold switch layer 220, the ferroelectric layer 240 and the ovonic threshold switch layer 220 may have a thickness ratio of 1:4 to 1:8.

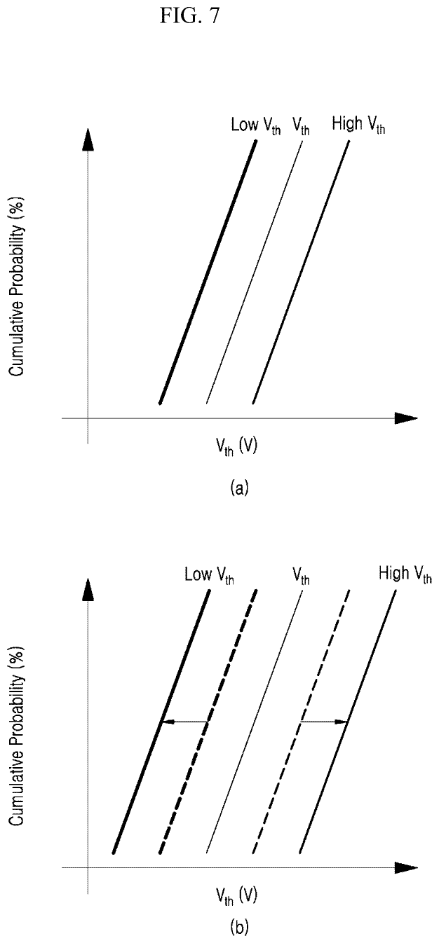

The ferroelectric layer 240, together with the ovonic threshold switch layer 220, constitutes a selection element. The ferroelectric layer 240 may contribute to securing a larger memory window, compared to the conventional art, by providing an additional memory window effect due to current polarization when a pulse is applied, as illustrated in FIGS. 5 to 7.

In the present disclosure, the ovonic threshold switch layer 220 and the ferroelectric layer 240 may be in direct contact with each other. That is, no other material layer may be present between the ovonic threshold switch layer 220 and the ferroelectric layer 240. Due to the absence of another material layer between the ovonic threshold switch layer 220 and the ferroelectric layer 240, the polarization phenomenon of the ferroelectric layer 240 may affect the ovonic threshold switch layer 220.

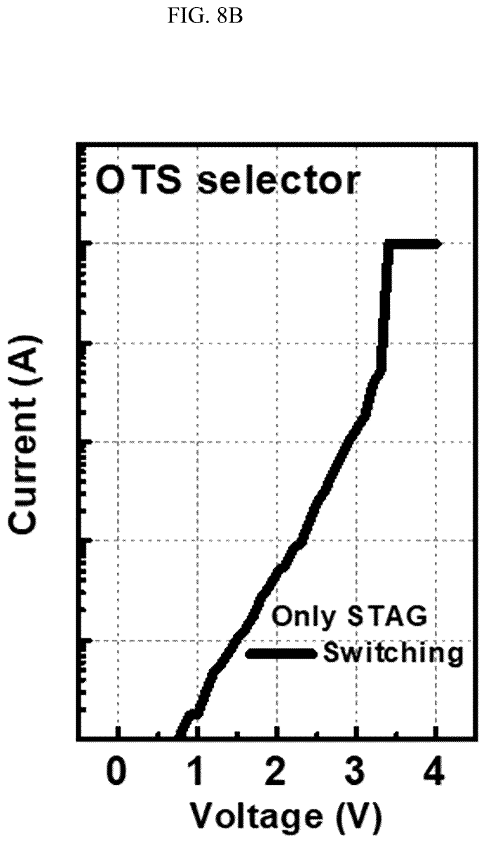

The selection element according to the present disclosure includes the ferroelectric layer 240 together with the ovonic threshold switch layer 220, and particularly includes a zirconium-doped hafnium oxide ferroelectric together with a chalcogenide ovonic threshold switch layer. As a result, a large threshold voltage variation may be induced through both the conventional threshold voltage variation effect of the chalcogenide and an additional change caused by the remanent polarization, thereby maximizing the memory window. As can be seen in FIG. 7, depending on the change in polarization direction, the low threshold voltage state requires a lower voltage than that of the conventional selection element, and the high threshold voltage state requires a higher voltage.

In the present disclosure, the ferroelectric layer may preferably include hafnium oxide doped with zirconium, titanium, or silicon, and more preferably, may include hafnium oxide doped with zirconium. In the case of hafnium oxide doped with zirconium, it exhibits excellent ferroelectric properties even in a thin film state of 10 nm or less, and is therefore suitable as the ferroelectric layer material of the selection element according to the present disclosure.

Hafnium oxide doped with zirconium may be represented by HfₓZr₁₋ₓO₂, where x may preferably range from 0.25 to 0.75. That is, the atomic ratio of zirconium to hafnium may be from 1:3 to 3:1. The atomic ratio of zirconium to hafnium is more preferably from 1:2 to 2:1, and most preferably 1:1, at which the ferroelectric property may be maximized. Such an atomic ratio of zirconium to hafnium may be adjusted by alternately depositing HfO₂ and ZrO₂ in single layers through an atomic layer deposition method, while controlling the deposition time or the number of deposition cycles. An excellent memory window expansion efficiency may be obtained at the above zirconium-to-hafnium ratio. When the zirconium content is excessive beyond the above range, antiferroelectric characteristics may appear, which may result in the loss of the remanent polarization effect that provides non-volatile characteristics. Additionally, when the hafnium content is excessive, ferroelectric characteristics may not appear, so polarization is not formed, which may result in the inability to produce an additional memory window increase effect.

Meanwhile, after depositing zirconium-doped hafnium oxide by an atomic layer deposition method, it is preferable to perform annealing at about 400 to 800° C. so that ferroelectric characteristics may be exhibited.

The ferroelectric layer 240 may be formed to have a thickness of about 20 nm or less. Preferably, in terms of thinning the element and making the resistance level similar to that of the ovonic threshold switch layer, the ferroelectric layer 240 may be formed to have a thickness of 10 nm or less. For example, in the case of a zirconium-doped hafnium oxide ferroelectric layer, excellent ferroelectric properties may be exhibited even at a thickness of 10 nm or less, enabling the effect of expanding the memory window.

Preferably, the ferroelectric layer and the ovonic threshold switch layer may have a thickness ratio of 1:4 to 1:8. At such a thickness ratio, the ferroelectric layer and the ovonic threshold switch layer may have similar resistance levels, allowing smooth voltage distribution. As a result, the threshold voltage may vary depending on the pulse direction, thereby producing an expanded memory window. If the thickness ratio between the ferroelectric layer and the ovonic threshold switch layer deviates from 1:4 to 1:8 and the resistance of one side becomes too high, most of the voltage will be applied to either the ferroelectric layer or the ovonic threshold switch layer alone, making it impossible to obtain the memory window expansion effect.

Additionally, the selection element according to the present disclosure may have a size of about 100 nm×100 nm to about 500 nm×500 nm. The element area also affects the resistance of the ferroelectric layer and the ovonic threshold switch layer, and the memory window expansion effect may be sufficiently obtained through the element area within the above range and the aforementioned thickness ratio.

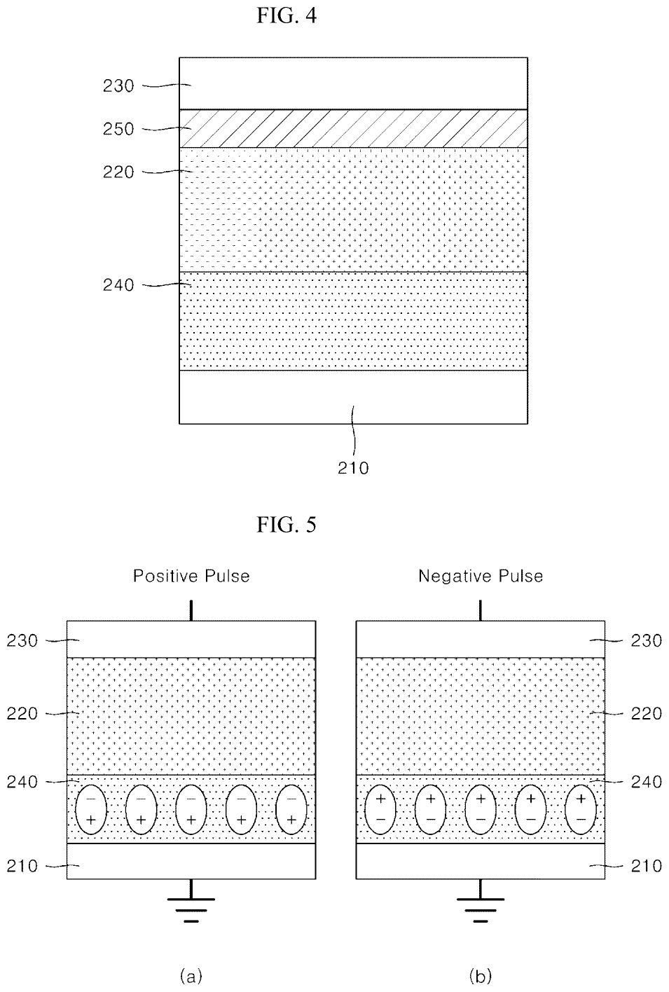

FIG. 3 schematically illustrates a x-point memory device including the selection element structure of FIG. 2. In FIG. 3(a), an example of a 1×1 single x-point memory device is shown, and in FIG. 3(b), an example of a 3×3 x-point memory device is shown.

The illustrated x-point memory device includes m bit lines (BL) where m is a natural number of 1 or more, n word lines (WL) where n is a natural number of 1 or more, and selection elements disposed between the bit lines and the word lines. The selection element is formed in a stacked structure of an ovonic threshold switch layer 220 and a ferroelectric layer 240.

The m bit lines (BL) are arranged in a first direction. The n word lines (WL) are disposed apart from the m bit lines (BL) and are arranged in a second direction intersecting the first direction. The bit lines (BL) may correspond to the first electrode 210 of FIG. 2, and the word lines (WL) may correspond to the second electrode 230 of FIG. 2.

The selection elements disposed between the m bit lines and the n word lines may be formed in a total of m×n so as to correspond to each bit line and each word line.

The selection element is formed in a stacked structure of an ovonic threshold switch layer 220 and a ferroelectric layer 240. The ferroelectric layer 240 may be disposed between the ovonic threshold switch layer 220 and the bit line (BL). In another example, the ferroelectric layer 240 may be disposed between the ovonic threshold switch layer 220 and the word line (WL).

The selection element according to the present disclosure may be utilized as a selection element of an x-point memory device, such as the example illustrated in FIG. 3. By configuring the selection element with the ferroelectric layer 240 together with the ovonic threshold switch layer 220, a wider memory window may be secured compared to the conventional case.

More specifically, the x-point memory device according to the present disclosure includes: m bit lines (BL), where m is a natural number of 1 or more, arranged in a first direction; n word lines (WL), where n is a natural number of 1 or more, disposed apart from the m bit lines (BL) and arranged in a second direction intersecting the first direction; and m×n selection elements disposed between the m bit lines (BL) and the n word lines (WL), the selection elements being formed in a stacked structure of an ovonic threshold switch layer 220 and a ferroelectric layer 240.

The ovonic threshold switch layer 220 and the ferroelectric layer 240 are in direct contact, that is, no other material layer may be present between the ovonic threshold switch layer 220 and the ferroelectric layer 240.

The ferroelectric layer 240 may include zirconium-doped hafnium oxide.

The ovonic threshold switch layer 220 may include a chalcogenide compound.

The ferroelectric layer 240 may include zirconium-doped hafnium oxide. The atomic ratio of zirconium to hafnium may be in the range of 1:3 to 3:1. More preferably, the atomic ratio of zirconium to hafnium may be in the range of 1:2 to 2:1. Most preferably, the atomic ratio of zirconium to hafnium may be 1:1.

The ferroelectric layer 240 may have a thickness of 10 nm or less.

The ferroelectric layer 240 and the ovonic threshold switch layer 220 may have a thickness ratio in the range of 1:4 to 1:8. This may reduce the difference in resistance levels between the ferroelectric layer 240 and the ovonic threshold switch layer 220.

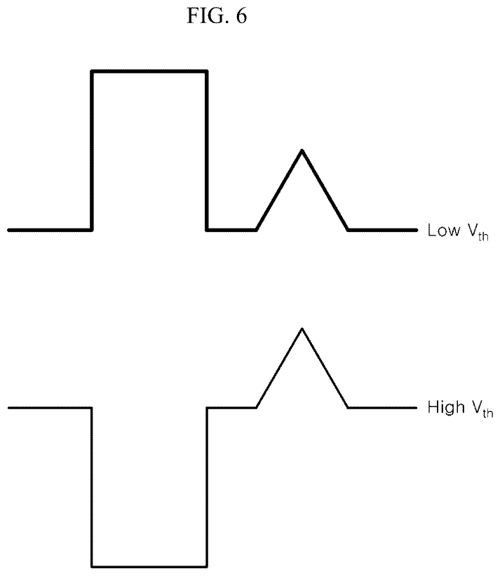

FIG. 4 schematically illustrates a selection element for a memory device according to another embodiment of the present disclosure.

Similar to the selection element shown in FIG. 2, the selection element shown in FIG. 4 includes a first electrode 210, an ovonic threshold switch layer 220, a second electrode 230, and a ferroelectric layer 240.

However, the selection element illustrated in FIG. 4 may additionally include a carbon layer 250 between the ovonic threshold switch layer 220 and the second electrode 230. The carbon layer serves to prevent deterioration of characteristics caused by mixing between the material constituting the second electrode 230 and the material constituting the ovonic threshold switch layer 220 as switching is repeated.

The carbon layer 250 may be formed of, for example, an amorphous carbon layer. The carbon layer 250 may be formed to have a thickness of about 2 to 20 nm.

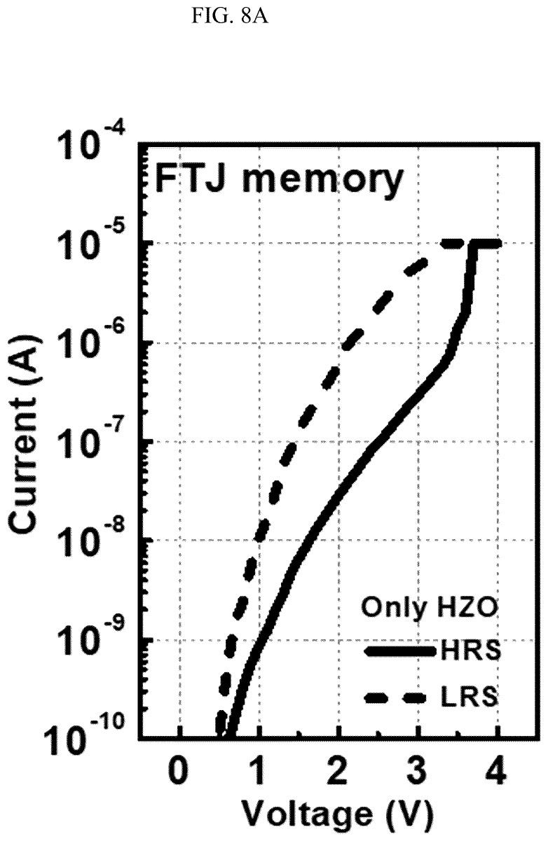

FIG. 5 illustrates the direction of remanent polarization of a ferroelectric layer according to the pulse direction during a write operation. FIG. 6 illustrates write pulses for creating a low threshold voltage state and a high threshold voltage state. FIG. 7 illustrates the difference in the degree of threshold voltage variation between a single structure and an integrated structure, showing the additional effect achieved in the integrated structure.

Referring to FIGS. 5 and 6, when a positive (+) pulse is applied to the second electrode 230, which is closer to the ovonic threshold switch layer, and the first electrode 210 is grounded, polarization occurs in which electrons are displaced toward the ovonic threshold switch layer 220 and holes are displaced in the opposite direction. Conversely, when a negative (−) pulse is applied to the second electrode 230, polarization occurs in which holes are displaced toward the ovonic threshold switch layer 220 and electrons are displaced in the opposite direction. That is, as shown in FIG. 5, the polarization direction of the ferroelectric layer is reversed depending on the direction of the voltage applied to the selection element, which induces a shift in the threshold voltage from the perspective of the ovonic switching selection element. Additionally, as shown in FIG. 6, during the write operation, pulses in opposite directions are applied, followed by the application of a read pulse, thereby inducing a change in the threshold voltage of the integrated element.

Due to the polarization phenomenon of the ferroelectric layer 240, it may be observed that, compared to FIG. 7(a) in which the selection element is configured only with the ovonic threshold switch layer, FIG. 7(b) in which both the ovonic threshold switch layer and the ferroelectric layer are applied shows a significantly increased gap between a high threshold voltage (High Vth) and a low threshold voltage (Low Vth), thereby securing an additional memory window.

A method of manufacturing a selection element according to an embodiment of the present disclosure includes a step of forming a first electrode, a step of forming a ferroelectric layer, a step of forming an ovonic threshold switch layer, and a step of forming a second electrode.

In the first electrode forming step, a first electrode 210 is formed on a substrate.

In the ferroelectric layer forming step, a ferroelectric layer 240 is formed on the first electrode.

The ferroelectric layer 240 may include zirconium-doped hafnium oxide. An atomic ratio of zirconium to hafnium may be in the range of 1:3 to 3:1.

The ferroelectric layer 240 may have a thickness of 10 nm or less. For this purpose, the ferroelectric layer 240 is preferably formed by an atomic layer deposition method. After atomic layer deposition, it is preferable to perform annealing at about 400-800° C. so that ferroelectric properties may be exhibited.

In the ovonic threshold switch layer forming step, an ovonic threshold switch layer 220 is formed on the ferroelectric layer.

In the ovonic threshold switch layer formation step, the ovonic threshold switch layer 220 may be formed such that the ovonic threshold switch layer 220 is in direct contact with the ferroelectric layer 240. For example, a tungsten layer may be formed on the ferroelectric layer 240 to crystallize the ferroelectric layer by annealing, and after removing the tungsten layer through etching, the ovonic threshold switch layer 220 may be formed on the crystallized ferroelectric layer.

The ovonic threshold switch layer 220 may include a chalcogenide compound. Preferably, the ovonic threshold switch layer 220 may include a chalcogenide compound including at least one of Te and Se. More preferably, the ovonic threshold switch layer 220 may include SiTeAsGe or SiTeSeAsGe.

The ovonic threshold switch layer 220 may be formed by a sputtering method.

The ferroelectric layer formation step and the ovonic threshold switch layer formation step may be performed such that the resistance ratio between the ferroelectric layer 240 and the ovonic threshold switch layer 220 is in a range of 1:3 to 3:1.

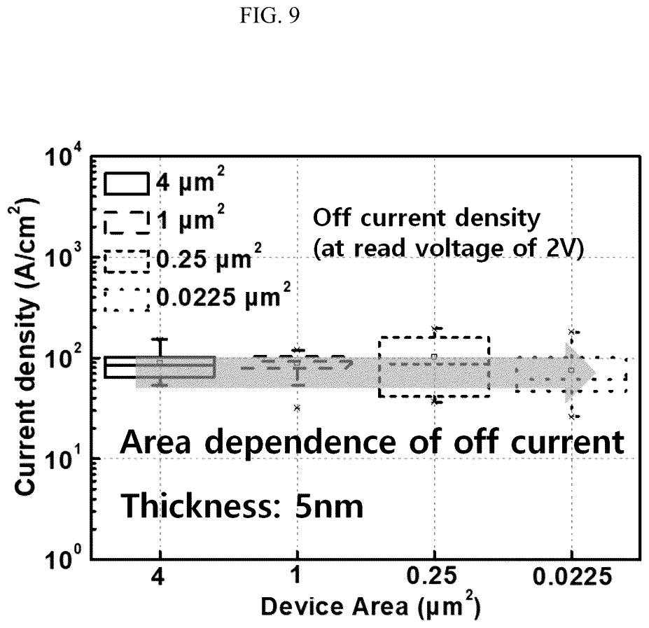

FIG. 8A illustrates the change in current value according to voltage for a ferroelectric material alone that forms the ferroelectric layer in a ferroelectric tunnel junction memory (FTJ memory). In FIG. 8A, HZO (with a molar ratio of Zr:Hf=1:1) was used as the ferroelectric layer, and results are shown for a high resistance state (HRS) and a low resistance state (LRS). FIG. 8B illustrates the current value according to voltage for a chalcogenide compound alone that forms the ovonic threshold switch layer. In FIG. 8B, SiTeAsGe (STAG) was used as the chalcogenide compound, and the switching operation is shown as a voltage-current curve.

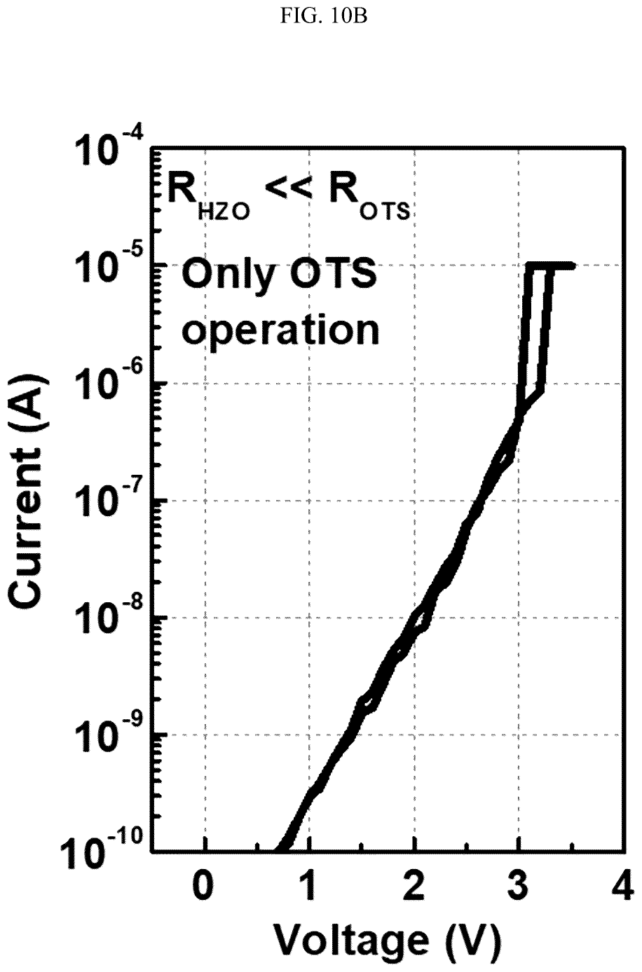

Based on the results of FIGS. 8A and 8B, as well as the results of FIGS. 10A and 10B described later, it is determined that, for desired memory operation to be implemented during integration, the resistance ratio between the ferroelectric layer and the ovonic threshold switch layer should be within a range of 1:3 to 3:1 within the operating voltage.

The resistance ratio between the ferroelectric layer 240 and the ovonic threshold switch layer 220 may be adjusted, for example, by the area of the ferroelectric layer 240, the annealing temperature of the ferroelectric layer 240, and/or the thickness of the ferroelectric layer 240 and/or the ovonic threshold switch layer 220.

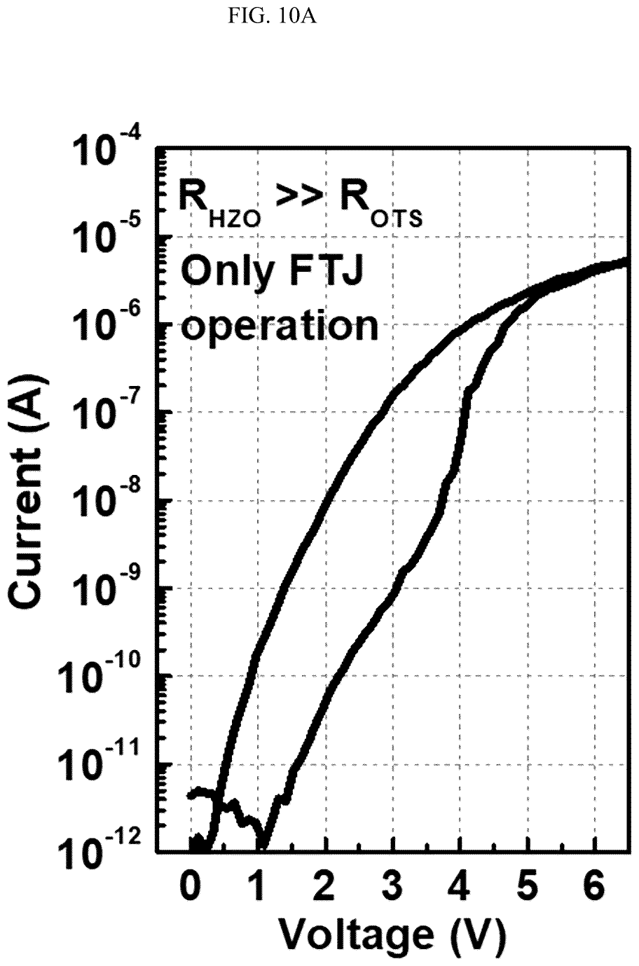

FIG. 9 is a graph showing that the off current density of the ferroelectric layer is maintained as the area of the ferroelectric material is reduced.

Depending on the area of the HZO (with a molar ratio of Zr:Hf=1:1) ferroelectric layer, for example, as it decreases from 4 um2 to 0.0225 um2, the off current density is maintained but the off current value changes, and accordingly, the resistance of the ferroelectric layer may vary. Accordingly, the resistance ratio between the ferroelectric layer 240 and the ovonic threshold switch layer 220 may also be adjusted by the area of the ferroelectric layer 240.

Additionally, by adjusting the thickness of the ovonic threshold switch layer, the resistance ratio between the ferroelectric layer 240 and the ovonic threshold switch layer 220 may be adjusted.

FIGS. 10A and 10B are current-voltage graphs illustrating the operation of the element when integrated under a condition where there is a large resistance difference between the ferroelectric layer and the ovonic threshold switch layer.

In FIGS. 10A and 10B, HZO (molar ratio Zr:Hf=1:1) was used as the ferroelectric layer 240, and SiTeAsGe (STAG) was used as the ovonic threshold switch layer.

Referring to FIG. 10A, it may be seen that when the resistance of the ferroelectric layer is excessively high, only general ferroelectric tunnel junction characteristics appear, and when the resistance of the ovonic threshold switch layer is excessively high, only ovonic threshold switch selection element characteristics appear.

Accordingly, it may be understood that it is preferable for the resistance ratio between the ferroelectric layer 240 and the ovonic threshold switch layer 220 to be small, for example, in a range such as from 1:3 to 3:1.

After the step of forming the ovonic threshold switch layer, the method may additionally include a step of forming a carbon layer 250 on the ovonic threshold switch layer.

In the step of forming the second electrode, the second electrode 230 is formed on the ovonic threshold switch layer, or, when a carbon layer is formed, on the carbon layer.

The first electrode 210 and/or the second electrode 230 may be formed by a sputtering method.

### EXAMPLE

Hereinafter, the present disclosure will be described in more detail through examples. It should be noted, however, that the following examples are merely intended to illustrate and further detail the present disclosure, and are not intended to limit the scope of the present disclosure.

### 1. Manufacture of the Selection Element

### (1) Example 1

A SiO₂ wafer having a TiN first electrode with a size of 150×150 nm² was prepared, and a ferroelectric layer having a thickness of about 5 nm was formed by depositing zirconium-doped hafnium oxide (atomic ratio Zr:Hf=1:1) on the first electrode by atomic layer deposition at 250° C., followed by annealing at 600° C. for 1 minute.

Subsequently, an SiTeAsGe ovonic threshold switch layer having a thickness of about 30 nm was formed by sputtering. Subsequently, an amorphous carbon layer having a thickness of about 4 nm was deposited by sputtering. Subsequently, a tungsten (W) second electrode was formed by sputtering. To avoid crystallization of the SiTeAsGe ovonic threshold switch layer, the carbon layer and the second electrode layer were formed without high-temperature heat treatment.

### (2) Comparative Example 1

A SiO₂ wafer having a TiN first electrode with a size of 150×150 nm² was prepared, and an SiTeAsGe ovonic threshold switch layer having a thickness of about 30 nm was formed on the first electrode by sputtering. Subsequently, an amorphous carbon layer having a thickness of about 4 nm was deposited by sputtering. Subsequently, a tungsten (W) second electrode was formed by sputtering. To avoid crystallization of the SiTeAsGe ovonic threshold switch layer, the carbon layer and the second electrode layer were formed without high-temperature heat treatment.

### 2. Evaluation Results of Characteristics

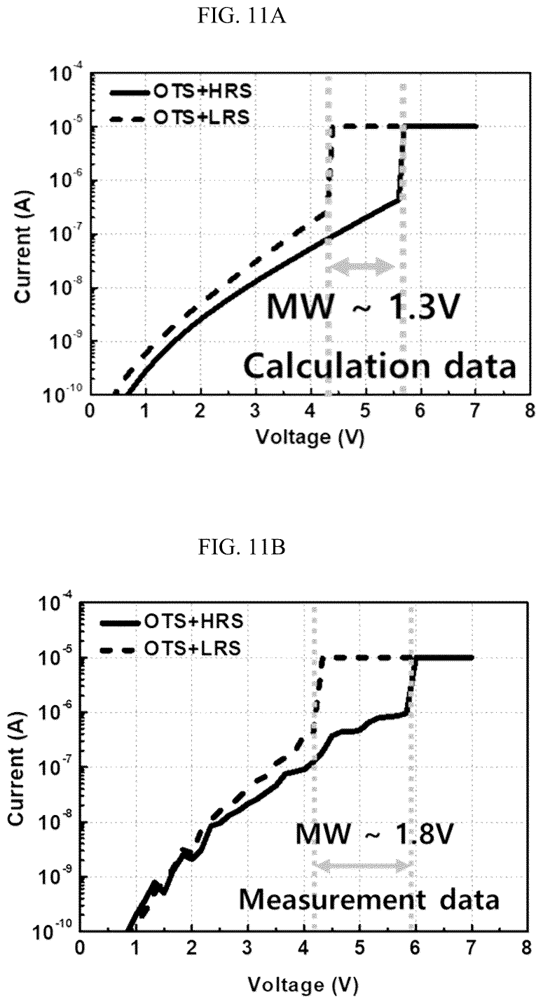

FIG. 11A illustrates a current-voltage curve indicating the expected magnitude of threshold voltage variation, considering the resistance of the ferroelectric layer and the ovonic switching layer, and FIG. 11B illustrates a current-voltage curve obtained through actual measurement.

Referring to FIGS. 11A and 11B, in the case of the selection element according to Example 1, it can be seen that, in addition to the threshold voltage variation effect of the conventional single ovonic switching selection element, an additional voltage variation was induced by the remanent polarization of the ferroelectric layer. This demonstrates that the ferroelectric buffer layer is effective as a solution to overcome the limitation of the conventional single ovonic switching selection element, which has a small memory window.

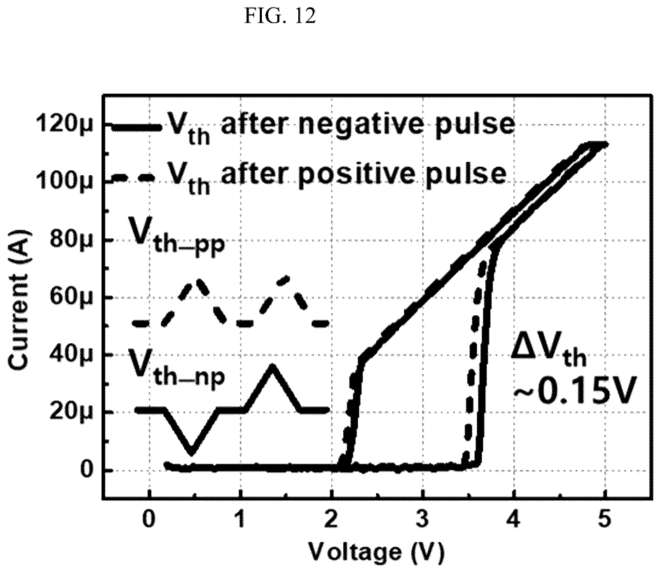

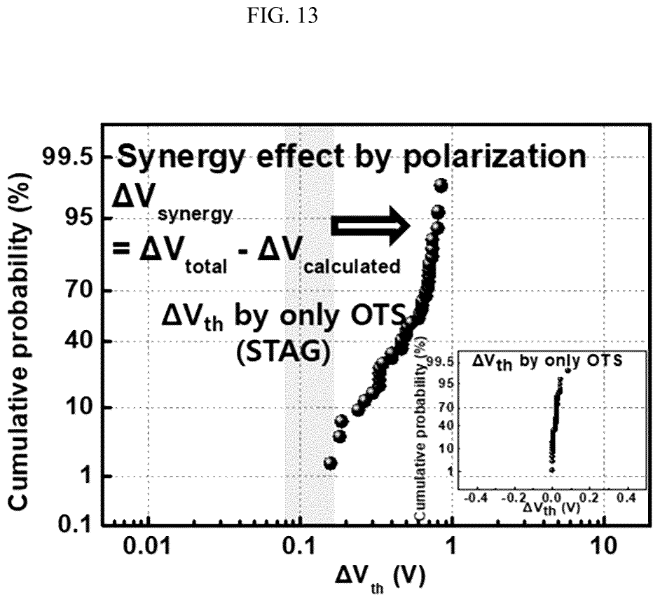

FIG. 12 illustrates a current-voltage curve showing the threshold voltage according to pulse direction in a single memory with an ovonic switching-based selection element using a Te-based material. FIG. 13 illustrates the additional threshold voltage variation obtained purely by the ferroelectric layer.

Referring to FIG. 12, when the memory window is calculated by considering only the resistance values of the ferroelectric layer and the ovonic switching selection element layer without taking the remanent polarization into account, there is a limitation in inducing a large threshold voltage variation. To demonstrate that an additional threshold voltage variation can be induced by the magnitude of the remanent polarization of the ferroelectric layer, the additional threshold voltage variation effect due to the ferroelectric layer, obtained from actual measurements by taking into account the magnitude of the threshold voltage variation of the ovonic switching selection element, may be determined as shown in FIG. 13. Based on this, it can be seen that the ferroelectric buffer layer may also be applied to Se-based single ovonic switching selection elements, which exhibit a relatively large threshold voltage variation effect.

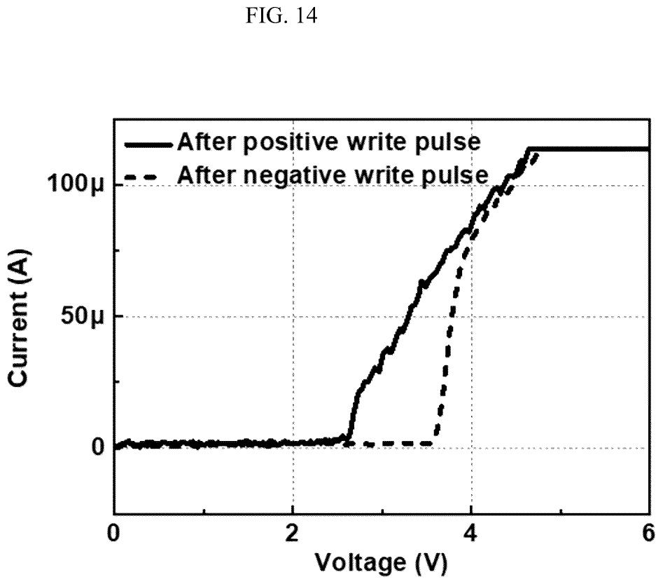

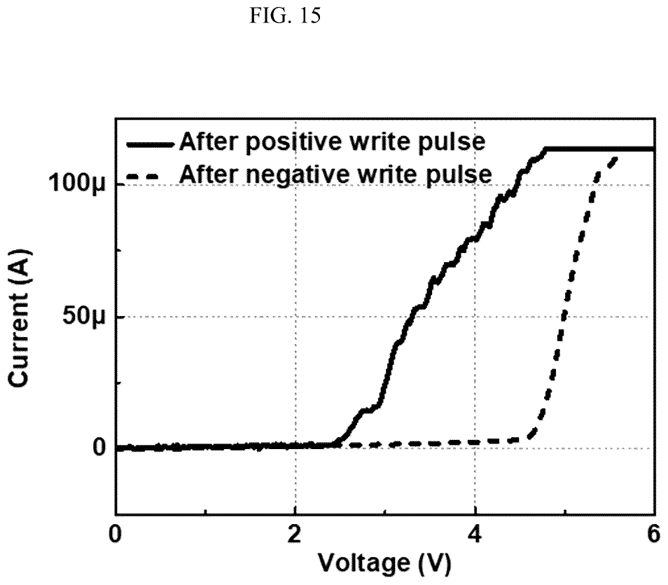

FIG. 14 shows current-voltage curves representing the threshold voltage of a single memory element according to the pulse direction when an ovonic switching-based selection element according to Comparative Example 2 is applied. FIG. 15 shows current-voltage curves representing the threshold voltage of a single memory element according to the pulse direction when a selection element according to Example 2 is applied.

Example 2 and Comparative Example 2 were manufactured in the same manner as the selection elements according to Example 1 and Comparative Example 1, except that, instead of the SiTeAsGe ovonic threshold switch layer of Example 1 and Comparative Example 1, a SiTeSeAsGe ovonic threshold switch layer including additional Se was formed.

Referring to FIGS. 14 and 15, it can be seen that when the selection element according to Example 2 is applied, a memory device having a large memory window of 2 V or more may be implemented, compared to when the selection element according to Comparative Example 2 is applied.

While the above description has been made with reference to embodiments of the present disclosure, various changes and modifications may be made by those of ordinary skill in the art. Therefore, it will be understood that such changes and modifications are included within the scope of the present disclosure, as long as they do not depart from the scope of the present disclosure.

What is claimed is:

1. A selection element comprising:
a first electrode;
an ovonic threshold switch layer disposed on the first electrode; and
a second electrode disposed on the ovonic threshold switch layer,
wherein a ferroelectric layer is disposed between the first electrode and the ovonic threshold switch layer, and the ferroelectric layer and the ovonic threshold switch layer have a thickness ratio of 1:4 to 1:8.

2. The selection element according to claim 1, wherein the ovonic threshold switch layer and the ferroelectric layer are in direct contact with each other.

3. The selection element according to claim 1, wherein the ferroelectric layer includes zirconium-doped hafnium oxide.

4. The selection element according to claim 3, wherein an atomic ratio of zirconium to hafnium is 1:3 to 3:1.

5. The selection element according to claim 4, wherein an atomic ratio of zirconium to hafnium is 1:2 to 2:1.

6. The selection element according to claim 1, wherein the ferroelectric layer has a thickness of 10 nm or less.

7. The selection element according to claim 1, wherein the ovonic threshold switch layer includes a chalcogenide compound.

8. The selection element according to claim 7, wherein the ovonic threshold switch layer includes a chalcogenide compound including at least one of Te and Se.

9. The selection element according to claim 1, wherein a carbon layer is further disposed between the ovonic threshold switch layer and the second electrode.

10. An x-point memory device comprising:
m bit lines arranged in a first direction, where m is a natural number of 1 or more;
n word lines arranged in a second direction intersecting the first direction and disposed apart from the m bit lines, where n is a natural number of 1 or more; and
m×n selection elements disposed between the m bit lines and the n word lines,
wherein each of the selection elements is formed in a stacked structure of an ovonic threshold switch layer and a ferroelectric layer, and the ferroelectric layer and the ovonic threshold switch layer have a thickness ratio of 1:4 to 1:8.

11. The memory device according to claim 10, wherein the ovonic threshold switch layer and the ferroelectric layer are in direct contact.

12. The memory device according to claim 11, further comprising a carbon layer disposed between the selection element and the word line.

13. The memory device according to claim 10, further comprising a ferroelectric layer including zirconium-doped hafnium oxide.

14. The memory device according to claim 13, wherein an atomic ratio of zirconium to hafnium is 1:3 to 3:1.

15. The memory device according to claim 14, wherein an atomic ratio of zirconium to hafnium is 1:2 to 2:1.

16. The memory device according to claim 10, wherein the ferroelectric layer has a thickness of 10 nm or less.

17. The memory device according to claim 10, wherein the ovonic threshold switch layer includes a chalcogenide compound.

18. The memory device according to claim 17, wherein the ovonic threshold switch layer includes a chalcogenide compound containing at least one of Te and Se.
